(19) United States
(12) Patent Application Publication
(10) Pub. No.: US 2026/0059814 A1
(43) Pub. Date: Feb. 26, 2026

(54) SILICON CARBIDE WAFER, METHOD OF MANUFACTURING A SILICON CARBIDE WAFER, SILICON CARBIDE SEMICONDUCTOR DEVICE, AND METHOD OF MANUFACTURING A SILICON CARBIDE SEMICONDUCTOR DEVICE

(71) Applicant: FUJI ELECTRIC CO., LTD., Kawasaki-shi (JP)

(72) Inventor: Mina OHSE, Matsumoto-city (JP)

(73) Assignee: FUJI ELECTRIC CO., LTD., Kawasaki-shi (JP)

(21) Appl. No.: 19/376,529

(22) Filed: Oct. 31, 2025

Related U.S. Application Data
(63) Continuation of application No. PCT/JP2024/035348, filed on Oct. 2, 2024.

(30) Foreign Application Priority Data
Nov. 28, 2023 (JP) 2023-201150

(51) Int. Cl. H10D 62/53; H01L 21/22; H10D 30/66; H10D 62/10; H10D 62/832

(52) U.S. Cl. CPC H10D 62/53; H01L 21/221; H10D 30/668; H10D 62/109; H10D 62/8325

(57) ABSTRACT

A silicon carbide wafer, including: a semiconductor substrate containing silicon carbide and having a first surface and a second surface opposite to each other; an epitaxial layer provided at the first surface of the semiconductor substrate and having a dopant concentration lower than that a dopant concentration of the semiconductor substrate; and a crystal defect introduced region provided in the semiconductor substrate, at a predetermined depth from the first surface of the semiconductor substrate, the crystal defect introduced region being in contact with the epitaxial layer and containing a number of point defects that are atomic vacancies created by irradiation of an electron beam on the semiconductor substrate.

### CROSS REFERENCE TO RELATED APPLICATIONS

This is a continuation application of International Application PCT/JP2024/035348 filed on Oct. 2, 2024 which claims priority from a Japanese Patent Application No. 2023-201150 filed on Nov. 28, 2023, the contents of which are incorporated herein by reference.

### BACKGROUND OF THE INVENTION

### 1. Field of the Invention

Embodiments of the present disclosure relate to silicon carbide wafer, a method of manufacturing a silicon carbide wafer, a silicon carbide semiconductor device, and a method of manufacturing a silicon carbide semiconductor device.

### 2. Description of the Related Art

Japanese Laid-Open Patent Publication No. 2021-15978 describes a technique for suppressing bipolar degradation in a semiconductor device by ion-implanting a dopant or introducing crystal defects that act as minority carrier lifetime killers in a portion of a silicon carbide (SiC) semiconductor wafer, from a first surface to a certain depth, and thereafter performing epitaxial growth of a SiC layer on the first surface of the SiC semiconductor wafer, and forming a semiconductor device in or on the SiC layer. S. Harada et al, Suppression of stacking fault expansion in a 4H-SiC epitaxial layer by proton irradiation, Scientific Reports, 2002, 12:13542 describes a technique for suppressing bipolar degradation by introducing point defects or hydrogen into a SiC epitaxial layer formed on a SiC starting substrate.

### SUMMARY OF THE INVENTION

According to an embodiment of the present disclosure, a silicon carbide wafer includes: a semiconductor substrate containing silicon carbide and having a first surface and a second surface opposite to each other; an epitaxial layer provided at the first surface of the semiconductor substrate and having a dopant concentration lower than that a dopant concentration of the semiconductor substrate; and a crystal defect introduced region provided in the semiconductor substrate, at a predetermined depth from the first surface of the semiconductor substrate, the crystal defect introduced region being in contact with the epitaxial layer and containing a number of point defects that are atomic vacancies created by irradiation of an electron beam on the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting an example of a structure of a silicon carbide wafer used in a silicon carbide semiconductor device according to an embodiment.

FIG. 2 is a cross-sectional view depicting an example of the structure of the silicon carbide wafer used in the silicon carbide semiconductor device according to the embodiment.

FIG. 3 is a cross-sectional view schematically depicting a state during the manufacturing of the silicon carbide wafer used in the silicon carbide semiconductor device according to the embodiment.

FIG. 4 is a cross-sectional view schematically depicting a state during the manufacturing of the silicon carbide wafer used in the silicon carbide semiconductor device according to the embodiment.

FIG. 5 is a cross-sectional view schematically depicting another example of a state during the manufacturing of the silicon carbide wafer used in the silicon carbide semiconductor device according to an embodiment.

FIG. 6 is an explanatory diagram schematically depicting a principle of BPD-TED conversion during the manufacture of the silicon carbide wafer according to the embodiment.

FIG. 7 is a cross-sectional view depicting an example of a structure of a silicon carbide semiconductor device according to an embodiment.

FIG. 8 is a cross-sectional view depicting examples of a structure of a silicon carbide substrate used in a silicon carbide semiconductor device of a reference example.

FIG. 9 is a cross-sectional view depicting examples of the structure of the silicon carbide substrate used in the silicon carbide semiconductor device of the reference example.

FIG. 10 is a cross-sectional view depicting examples of the structure of the silicon carbide substrate used in the silicon carbide semiconductor device of the reference example.

FIG. 11 is an explanatory diagram schematically depicting a principle of propagation of BPDs in a SiC wafer to an epitaxial layer grown by epitaxy on the SiC wafer in the reference example.

FIG. 12 is a graph depicting a typical temperature profile when epitaxial layers constituting a buffer layer and a drift layer are grown.

FIG. 13 is a graph depicting an experimentally obtained relationship between annealing time and the total number of penetrating BPDs in a silicon carbide wafer.

FIG. 14 is a top view schematically depicting temperature distribution at locations where penetrating-through BPDs increase at the surface of the silicon carbide wafer.

FIG. 15 is a characteristic diagram depicting distribution of shear stress at the surface of the silicon carbide wafer in an epitaxy growth furnace.

### DETAILED DESCRIPTION OF THE INVENTION

First, problems associated with the conventional techniques are discussed. In Japanese Laid-Open Patent Publication No. 2021-15978, the more densely a dopant acting as a lifetime killer for minority carriers is introduced into the SiC semiconductor wafer, or the deeper the dopant is introduced from the first surface of the SiC semiconductor wafer, the higher the dose and acceleration energy are for ion-implantation of the dopant, resulting in higher manufacturing costs. In Harada et al., the expansion of stacking faults (SFs) from basal plane dislocations (BPDs) already present in the SiC epitaxial layer is suppressed, but the propagation of BPDs from the SiC starting substrate to the epitaxial layer during epitaxial growth cannot be suppressed.

An outline of embodiments of the present disclosure is described. (1) A silicon carbide wafer according to one aspect of the present disclosure is as follows. An epitaxial layer having a dopant concentration that is lower than a dopant concentration of the semiconductor substrate is disposed on a front surface of a semiconductor substrate containing silicon carbide. A crystal defect introduced region containing a relatively large number of point defects is disposed in the semiconductor substrate, in contact with the epitaxial layer. The crystal defect introduced region is a predetermined depth from the first surface of the semiconductor substrate.

According to the above disclosure, a silicon carbide wafer may be provided in which BPDs in the semiconductor substrate are converted to TEDs with high efficiency at the interface with the epitaxial layer, thereby reducing the number of BPDs in the epitaxial layer.

(2) In the silicon carbide wafer according to the present disclosure, in the above (1), the semiconductor substrate may contain more point defects than the epitaxial layer.

According to the above disclosure, a silicon carbide wafer may be provided that contains minority carrier lifetime killers at a high density.

(3) In the silicon carbide wafer according to the present disclosure, in the above (1) or (2), the crystal defect introduced region may be disposed only in a surface region of the first surface of the semiconductor substrate.

According to the above disclosure, BPDs in the semiconductor substrate are converted to TEDs with high efficiency at the interface with the epitaxial layer, thereby providing a silicon carbide wafer with a small number of BPDs in the epitaxial layer.

(4) In the silicon carbide wafer according to the present disclosure, in the above (3), the semiconductor substrate may contain a relatively large amount of hydrogen or nitrogen in the crystal defect introduced region.

According to the above disclosure, a silicon carbide wafer may be provided that contains minority carrier lifetime killers at a high density.

(5) A silicon carbide semiconductor device according to one aspect of the present disclosure is as follows. The silicon carbide wafer has a semiconductor substrate containing silicon carbide, an epitaxial layer having a dopant concentration that is lower than a dopant concentration of the semiconductor substrate, a crystal defect introduced region containing a relatively large number of point defects, a first main surface, and a second main surface. The epitaxial layer is disposed on the first surface of the semiconductor substrate. The crystal defect introduced region is disposed in the semiconductor substrate and is in contact with the epitaxial layer. The crystal defect introduced region is a predetermined depth from the first surface of the semiconductor substrate.

The first main surface is constituted by the outermost surface of the epitaxial layer. The second main surface is constituted by the back surface of the semiconductor substrate. A device structure is disposed in the silicon carbide wafer, at the first main surface thereof. The first electrode is disposed on the first main surface and electrically connected to the device structure. The second electrode is disposed on the second main surface. A pn junction that operates bipolarly between the first electrode and the second electrode is disposed in the silicon carbide wafer.

According to the above disclosure, BPDs in the semiconductor substrate are converted to TEDs with high efficiency at the interface with the epitaxial layer, allowing the use of a silicon carbide wafer with a small number of BPDs in the epitaxial layer. It is possible to suppress an increase in forward voltage (bipolar degradation) of the silicon carbide semiconductor device.

(6) A method of manufacturing a silicon carbide wafer according to one aspect of the present disclosure is as follows: An introduction process of introducing point defects from the front surface of a semiconductor substrate containing silicon carbide, to a predetermined depth to form a crystal defect introduced region is performed; and a film formation process of growing, by epitaxy, an epitaxial layer that is in contact with the crystal defect introduced region on the first surface of the semiconductor substrate and has a dopant concentration lower than that of the semiconductor substrate is performed.

According to the above disclosure, Si core partial dislocations of BPDs are unlikely to move in a vicinity of the first surface of the semiconductor substrate, and the efficiency at which BPDs in the starting substrate are converted to TEDs (BPD-TED conversion efficiency) may be stabilized. This makes it possible to highly and efficiently suppress the propagation of BPDs in the starting substrate.

(7) Furthermore, in the method of manufacturing the silicon carbide wafer according to the present disclosure, in the above (6), the film formation process may include raising the temperature in an epitaxy growth furnace to an epitaxial growth temperature with the semiconductor substrate inserted in the furnace, and growing by epitaxy the epitaxial layer at the epitaxial growth temperature.

According to the above disclosure, the BPD-TED conversion efficiency may be stabilized even when the temperature of the first surface of the semiconductor substrate, the temperature distribution in the semiconductor substrate, or the heating time of the semiconductor substrate vary and become unstable.

(8) A method of manufacturing a silicon carbide semiconductor device according to one aspect of the present disclosure is as follows: a first process of fabricating a silicon carbide wafer containing silicon carbide is performed; a second process of forming a device structure on a first main surface of the silicon carbide wafer is performed; a third process of forming a first electrode on the first main surface, the first electrode being electrically connected to the device structure; and a fourth process of forming a second electrode on a second main surface of the silicon carbide wafer. Prior to the third process, a pn junction that operates bipolarly is formed between the first electrode and the second electrode, in the silicon carbide wafer.

In the first process, an introduction process and a film formation process are performed thereby fabricating the silicon carbide wafer, with the outermost surface of the epitaxial layer serving as the first main surface and the back surface of the semiconductor substrate serving as the second main surface. In the introduction process, point defects are introduced from the first surface of the semiconductor substrate to a predetermined depth to form a crystal defect introduced region. In the film formation process, an epitaxial layer having a dopant concentration that is lower than a dopant concentration of the semiconductor substrate is grown by epitaxy on the first surface of the semiconductor substrate in contact with the crystal defect introduced region.

According to the above disclosure, BPDs in the semiconductor substrate are converted to TEDs with high efficiency at the interface with the epitaxial layer so that a silicon carbide semiconductor device can be manufactured using a silicon carbide wafer with a small number of BPDs in the epitaxial layer. This may suppress the bipolar degradation in the silicon carbide semiconductor device.

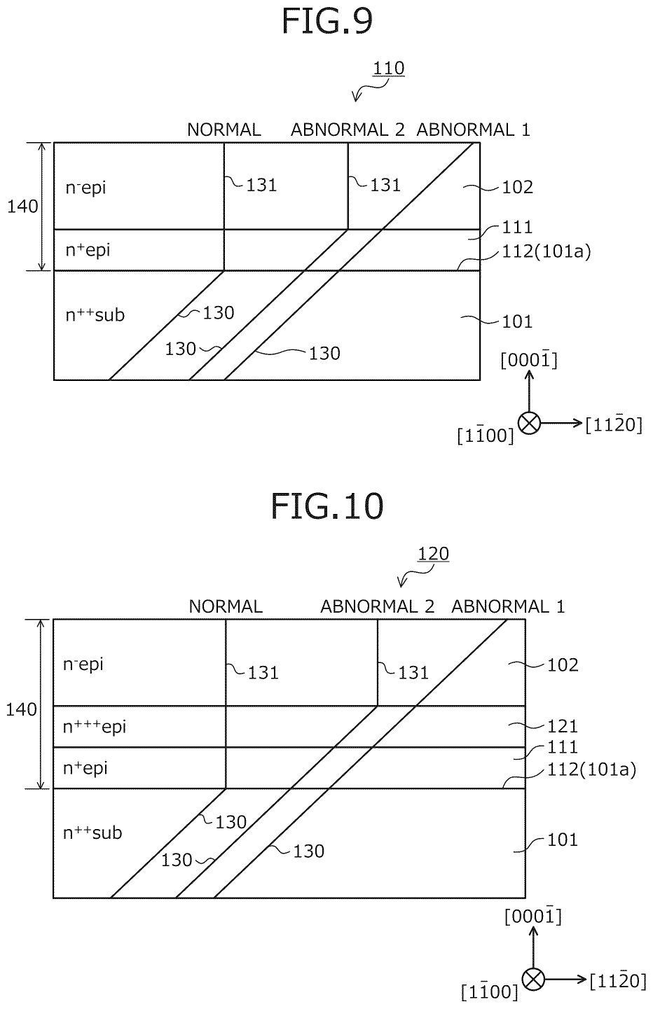

Findings underlying the present disclosure are discussed. FIGS. 8, 9, and 10 are cross-sectional views depicting examples of the structure of a silicon carbide substrate used in a silicon carbide semiconductor device of a reference example. The silicon carbide semiconductor device of the reference example uses an SiC wafer 100 (FIG. 8) formed by growing by epitaxy an n⁻-type epitaxial layer (denoted as n′epi) that constitutes a drift layer 102 on a front surface 101a of a starting substrate 101 (denoted as n⁺⁺ sub) containing silicon carbide (SiC) as a semiconductor material, or SiC wafers 110 and 120 (FIGS. 9 and 10: epitaxial wafers) in which one or more epitaxial layers (denoted as n⁺ epi and n⁺⁺⁺ epi) that constitute buffer layers 111 and 121 are disposed between the starting substrate 101 and the drift layer 102.

The starting substrate 101 is, for example, an n⁺⁺-type bulk substrate containing single crystal 4H-SiC (4-layer periodicity hexagonal silicon carbide). The front surface 101a of the starting substrate 101 is, for example, a (0001) plane, a so-called Si-plane, having a predetermined off-angle (for example, about 4°) in the <11-20> direction. Basal plane dislocations (BPDs) 130 are present in the starting substrate 101. The drift layer 102 and the buffer layers 111 and 121 are grown by epitaxy successively on the front surface 101a of the starting substrate 101 in an epitaxy growth furnace heated to a predetermined temperature, with the dopant concentrations and thicknesses appropriately controlled.

A device structure of a bipolar device such as an insulated gate bipolar transistor (IGBT) or a device structure that performs bipolar operation parasitically such as a metal oxide semiconductor field effect transistor (MOSFET: a MOS field effect transistor with an insulated gate having a three-layer structure of metal-oxide-semiconductor) is formed at the surface of the drift layer 102 opposite to the surface thereof facing the starting substrate 101 or in the drift layer 102, or both.

In the SiC wafer 100 depicted in FIG. 8, the basal plane dislocations (BPDs) 130 in the starting substrate 101 propagate (continue) to the drift layer 102 during epitaxial growth of the drift layer 102. When a certain amount of recombination energy is supplied to the BPDs 130 in the drift layer 102, the recombination energy being generated by the recombination of carriers (electrons and holes) in the drift layer 102 during bipolar operation (forward conduction) of the silicon carbide semiconductor device, the BPDs 130 expand while forming Shockley stacking faults (SFs) (not depicted). The forward voltage of the silicon carbide semiconductor device increases in proportion to the area of the SFs, which are planar defects generated in the drift layer 102 (bipolar degradation).

Thus, as in the SiC wafers 110 and 120 depicted in FIGS. 9 and 10, the n⁺-type buffer layer 111 having a dopant concentration that is higher than a dopant concentration of the drift layer 102 is grown by epitaxy on the front surface 101a of the starting substrate 101, thereby suppressing propagation of the BPDs 130 in the starting substrate 101 to the epitaxial layers (buffer layers 111 and 121 and drift layer 102) during epitaxial growth. The buffer layer 111 is a transition conversion layer that, during the epitaxial growth thereof, converts BPDs 130 in the starting substrate 101 into threading edge dislocations (TEDs) 131.

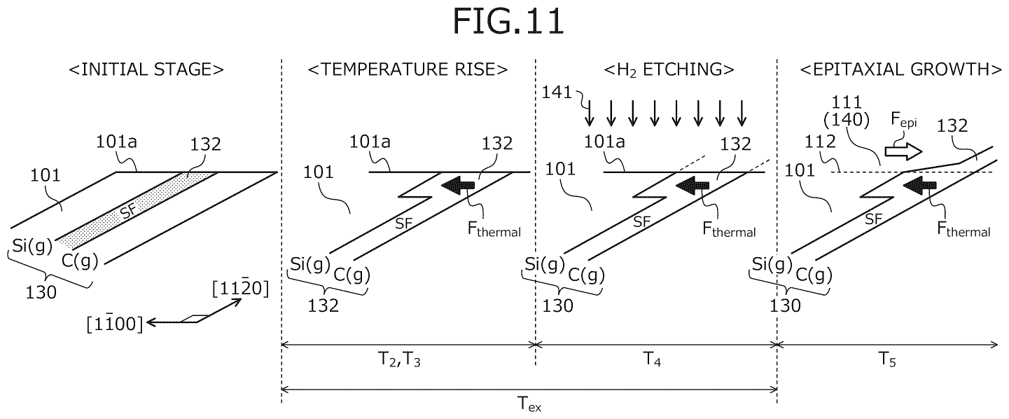

When the BPDs 130 in the starting substrate 101 are converted into the TEDs 131, the TEDs 131 also propagate to the drift layer 102 grown by epitaxy on the buffer layer 111. The TEDs 131 do not generate SFs 132 (refer to FIG. 11 described later) even when recombination energy is supplied. The n⁺⁺⁺-type buffer layer 121 having a dopant concentration that is higher than a dopant concentration of the buffer layer 111 may be disposed between the drift layer 102 and the buffer layer 111. In the buffer layer 121, recombination eliminates holes supplied from the drift layer 102 during bipolar operation of the silicon carbide semiconductor device, thereby suppressing the expansion of the SFs 132 from the BPDs 130 in the starting substrate 101.

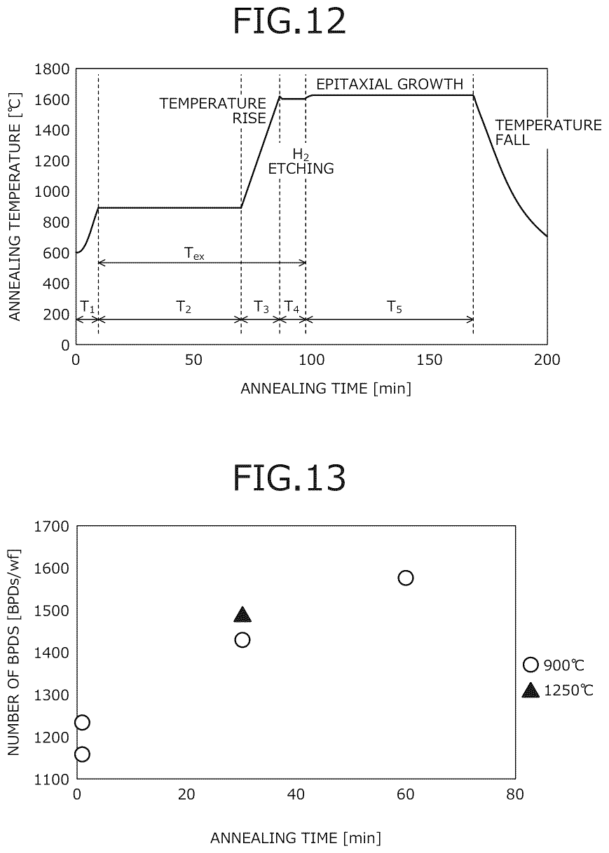

However, even when the buffer layer 111 is disposed between the starting substrate 101 and the drift layer 102, the BPDs 130 in the starting substrate 101 cannot be efficiently converted to the TEDs 131. A reason for this is as follows. FIG. 11 is an explanatory diagram schematically depicting a principle of the propagation of BPDs in a SiC wafer to an epitaxial layer grown by epitaxy on the SiC wafer in the reference example. FIG. 12 is a graph depicting a typical temperature profile when epitaxial layers constituting a buffer layer and a drift layer are grown. In FIG. 12, a horizontal axis represents the annealing time [minutes (min)] and a vertical axis represents the annealing (heat treatment) temperature [degrees C.].

FIG. 11 depicts a cross-sectional view of the starting substrate 101 before insertion into the epitaxy growth furnace (hereinafter referred to as the initial stage), a cross-sectional view of the starting substrate 101 during heating and hydrogen (H₂) etching before epitaxial growth, and a cross-sectional view of the starting substrate 101 during epitaxial growth (illustrated as “epitaxial growth” in FIGS. 11 and 12). In FIG. 11, the [11-20] direction is the step-flow growth direction of an epitaxial layer 140 grown by epitaxy on the front surface 101a of the starting substrate 101, and the [1-100] direction is a direction parallel to the front surface 101a of the starting substrate 101. Times T₂ to T₅ and Tₑₓ in FIG. 11 correspond to the annealing time in FIG. 12.

When the epitaxial layer 140 is grown by epitaxy on the front surface 101a of the starting substrate 101, the temperature in the epitaxy growth furnace containing the starting substrate 101 is increased or decreased according to the temperature profile depicted in FIG. 12. For example, after the starting substrate 101 is first inserted into the epitaxy growth furnace (not depicted), the temperature in the epitaxy growth furnace is increased to the epitaxial growth temperature (1600 degrees C. in this case) in two stages. That is, the temperature in the epitaxy growth furnace is increased to, for example, 900 degrees C. during a predetermined period T₁ (first-stage temperature rise), maintained at that temperature for a predetermined period T₂, and then further increased to a temperature close to the epitaxial growth temperature during a predetermined period T₃ (second-stage temperature rise).

With the temperature in the epitaxy growth furnace maintained near the epitaxial growth temperature, the front surface 101a of the starting substrate 101 is cleaned by dry etching (hydrogen etching) 141 using hydrogen (H₂) gas for a predetermined period T₄. Then, with the interior of the epitaxy growth furnace maintained at the epitaxial growth temperature, epitaxial layers 140 that constitute the buffer layers 111 and 121 and the drift layer 102 (refer to FIGS. 9 and 10) are grown successively by epitaxy on the front surface 101a of the starting substrate 101 during a predetermined time T₅, with the dopant concentration and thickness being appropriately controlled. After the epitaxial growth, the temperature in the epitaxy growth furnace is lowered to room temperature (e.g., by natural cooling).

The starting substrate 101 is a SiC starting wafer sliced from a SiC ingot grown by sublimation crystallography. As depicted in FIG. 11, a perfect dislocation BPD 130 is present in the basal plane of the starting substrate 101, which has a predetermined off-angle, and the BPD 130 is decomposed into two parallel Shockley partial dislocations Si(g) and C(g). A Shockley stacking fault (SF: the hatched portion of the initial starting substrate 101 in FIG. 11) 132 is present between the two Shockley partial dislocations Si(g) and C(g). FIG. 11 depicts a BPD 130 with a Burgers vector parallel to the step-flow growth direction of the epitaxial layer 140.

The silicon (Si) core partial dislocation Si(g) of the BPD 130 is in a state where the Si core partial dislocation Si(g) of the BPD 130 may move freely in a vicinity of the front surface 101a of the starting substrate 101. Therefore, during the temperature rise in the epitaxy growth furnace (temperature rise in FIG. 11), the Si core partial dislocation Si(g) of the BPD 130 in the starting substrate 101 receives a thermal stress Fₜₕₑᵣₘₐₗ in the [1-100] direction orthogonal to the step-flow growth direction of the epitaxial layer 140 in the vicinity of the front surface 101a of the starting substrate 101, and moves away from the C(carbon) core partial dislocation C(g). This partially widens the distance between the two Shockley partial dislocations Si(g) and C(g) of the BPD 130, and the SF 132 expands (increases in area) only in the vicinity of the front surface 101a of the starting substrate 101.

The expanded portion of the SF 132 is then removed by hydrogen etching 141 of the front surface 101a of the starting substrate 101. However, because the Si-core partial dislocation Si(g) continues to be subjected to the thermal stress Fₜₕₑᵣₘₐₗ during hydrogen etching 141, the expanded portion of the SF 132 is removed by hydrogen etching 141 and at the same time, the SF 132 expands again in a vicinity of the newly exposed surface on the front surface 101a of the starting substrate 101 (during hydrogen etching in FIG. 11). The expansion of the SF 132 occurs in the BPDs 130 that, among the multiple BPDs 130 in the starting substrate 101, have a Burgers vector parallel to the step-flow growth direction of the epitaxial layer 140.

When the epitaxial layer 140 that constitutes the buffer layer 111 is grown by epitaxy on the front surface 101a of the starting substrate 101, the Si-core partial dislocation Si(g) in the vicinity of the front surface 101a of the starting substrate 101 is subjected to a stress Fₑₚᵢ from the buffer layer 111 in a direction that pushes back the thermal stress Fₜₕₑᵣₘₐₗ (the opposite direction to the direction of the thermal stress Fₜₕₑᵣₘₐₗ). Since the apparent thermal stress Fₜₕₑᵣₘₐₗ in the vicinity of the front surface 101a of the starting substrate 101 decreases depending on the magnitude of the stress Fₑₚᵢ due to the buffer layer 111, the distance between the two Shockley partial dislocations Si(g) and C(g) of the BPD 130 in the starting substrate 101 is reduced.

When the distance between the two Shockley partial dislocations Si(g) and C(g) is reduced to a certain value or less in a vicinity of an interface 112 between the starting substrate 101 and the buffer layer 111, the BPD 130 is converted into the TED 131 at the interface 112 between the starting substrate 101 and the buffer layer 111 (see a normal TED 131 in FIGS. 9 and 10). Furthermore, a BPD 130 having a Burgers vector that is not parallel to the step-flow growth direction of the epitaxial layer 140 is converted into the TED 131 at the interface 112 between the starting substrate 101 and the buffer layer 111 (not depicted). The TED 131 propagates in the epitaxial layer 140 in a direction orthogonal to the front surface 101a of the starting substrate 101.

On the other hand, when the SF 132 is expanded excessively due to the thermal stress Fₜₕₑᵣₘₐₗ before the epitaxial growth of the epitaxial layer 140, the distance between the two Shockley partial dislocations Si(g) and C(g) does not decrease sufficiently even when the stress Fₑₚᵢ is applied by the buffer layer 111. As a result, the BPDs 130 in the starting substrate 101 are not converted to the TEDs 131 at the interface 112 between the starting substrate 101 and the buffer layer 111, but continue to propagate in the step-flow growth direction in the epitaxial layer 140 (abnormal BPDs 130 in FIGS. 9 and 10), or are converted to TEDs 131 with a delay in the epitaxial layer 140 (abnormal BPDs 130 in FIGS. 9 and 10).

FIG. 13 is a graph depicting an experimentally obtained relationship between the annealing time and the total number of penetrating BPDs in a silicon carbide wafer. In FIG. 13, the horizontal axis is annealing time [minutes], and the vertical axis is the total number of penetrating BPDs in the silicon carbide wafer [BPDs/wafer]. The silicon carbide wafer in FIG. 13 is an epitaxial wafer (corresponding to the SiC wafer 110 in FIG. 9) formed by depositing the epitaxial layer 140 on the front surface 101a of the starting substrate 101. FIG. 13 depicts the number of the BPDs 130 (hereinafter referred to as “penetrating-through BPDs”) propagating from the starting substrate 101 to the epitaxial layer 140 when the starting substrate 101 is annealed before epitaxial growth at different annealing temperatures and annealing times.

As depicted in FIG. 13, the longer the annealing time of the starting substrate 101 before epitaxial growth, the greater the number of penetrating-through BPDs in the silicon carbide wafer. Furthermore, from the results depicted in FIG. 13, it is inferred that the higher the annealing temperature of the starting substrate 101 before epitaxial growth, the greater the number of penetrating-through BPDs in the silicon carbide wafer. That is, the higher the thermal stress Fₜₕₑᵣₘₐₗ that the starting substrate 101 receives during the temperature rise in the epitaxy growth furnace in the temperature profile depicted in FIG. 11 (the higher the annealing temperature during temperature rise in the epitaxy growth furnace and the longer the annealing time), the more BPDs 130 increase in the epitaxial layer 140.

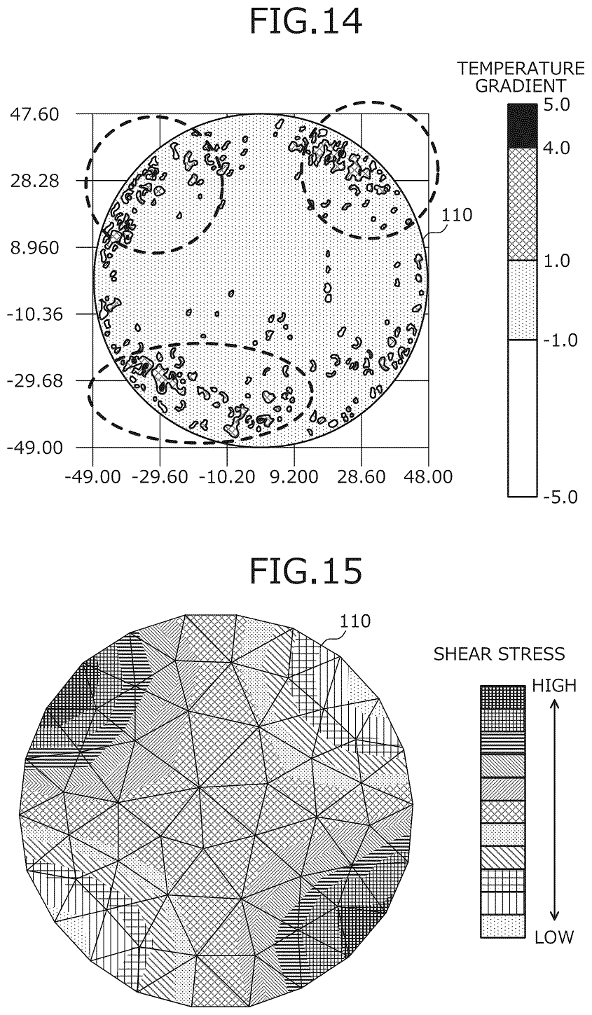

Of the silicon carbide wafers (SiC wafers 110) depicted in FIG. 13, the relationship between the penetrating-through BPD density and the thermal stress Fₜₕₑᵣₘₐₗ for samples in which the annealing temperature and annealing time of the starting substrate 101 before epitaxial growth were 1250 degrees C. and 30 minutes, respectively, are depicted in FIGS. 14 and 15. FIG. 14 is a top view schematically depicting the temperature distribution at locations where penetrating-through BPDs increase at the surface of the silicon carbide wafer (SiC wafer 110). In FIG. 14, for a silicon carbide wafer in which the starting substrate 101 was annealed before epitaxial growth, a dashed line surrounds a location in a rectangle of a predetermined area where the number of penetrating-through BPDs has increased by two or more, compared to a silicon carbide wafer in which the starting substrate 101 was not annealed before epitaxial growth.

FIG. 15 is a characteristic diagram depicting distribution of shear stress at the surface of the silicon carbide wafer (SiC wafer 110 depicted in FIG. 14) in the epitaxy growth furnace. FIG. 15 depicts the distribution of the thermal stress Fₜₕₑᵣₘₐₗ (distribution of shear stress) applied to the silicon carbide wafer (SiC wafer 110) in the <1-100> direction in the epitaxy growth furnace. As depicted in FIGS. 14 and 15, it was confirmed that the concentrated locations of threading BPDs at the surface of the silicon carbide wafer (SiC wafer 110) (locations where the number of threading BPDs increased, surrounded by dashed lines in FIG. 14) roughly coincide with locations where the thermal stress Fₜₕₑᵣₘₐₗ applied to the silicon carbide wafer (SiC wafer 110) is high in the epitaxy growth furnace. It was found that the higher the thermal stress Fₜₕₑᵣₘₐₗ the starting substrate 101 is subjected to, the greater the total number of threading BPDs in the silicon carbide wafer (SiC wafer 110).

Accordingly, during the period Tₑₓ during the temperature rise time (annealing time) in the epitaxy growth furnace in the temperature profile depicted in FIG. 11, when the annealing temperature is relatively high, the distance between the two Shockley partial dislocations Si(g) and C(g) of the BPD 130 in the starting substrate 101 increases in the vicinity of the front surface 101a of the starting substrate 101, and the SF 132 is likely to expand. The period Tₑₓ during which the annealing temperature is relatively high refers to the periods T₂ to T₄, excluding the first-stage temperature rise period T₁, of the total annealing time necessary for increasing the temperature in the epitaxy growth furnace. The SF 132 is particularly likely to expand in the starting substrate 101 during the second-stage temperature rise period T₄ during which the temperature is raised to 1500 degrees C. or higher.

The expansion of the distance between the two Shockley partial dislocations Si(g) and C(g) in the BPD 130 in the starting substrate 101 is proportional to the temperature of the wafer surface (front surface 101a of the starting substrate 101), the magnitude of the temperature difference at the wafer surface, and the length of heating time of the starting substrate 101 in an environment (temperature environment in the epitaxy growth furnace) in which the temperature is raised to a high temperature of about 1500 degrees C. or higher at a relatively large temperature gradient. When the temperature environment in the epitaxy growth furnace deteriorates before the epitaxial growth of the epitaxial layer 140, the efficiency at which the BPDs 130 in the starting substrate 101 are converted to the TEDs 131 (hereinafter referred to as BPD-TED conversion efficiency) becomes unstable.

Thus, with conventional techniques, there is a problem in that BPDs in the starting substrate are propagated. The present embodiment suppresses the propagation of BPDs by stabilizing the BPD-TED conversion efficiency.

Embodiments of a silicon carbide wafer, a method of manufacturing a silicon carbide wafer, a silicon carbide semiconductor device, and a method of manufacturing a silicon carbide semiconductor device according to the present disclosure will be described in detail below with reference to the accompanying drawings. In this specification and the accompanying drawings, layers and regions prefixed with n or p indicate that electrons or holes are the majority carriers, respectively. Furthermore, + and − appended to n or p indicate that the dopant concentration is higher or lower than that of layers or regions not prefixed with that symbol, respectively. Note that in the following description of the embodiments and the accompanying drawings, similar components are designated by the same reference numerals, and redundant explanations will be omitted. Further, in the present description, when Miller indices are described, “−” means a bar added to an index immediately after the “−”, and a negative index is expressed by prefixing “−” to the index.

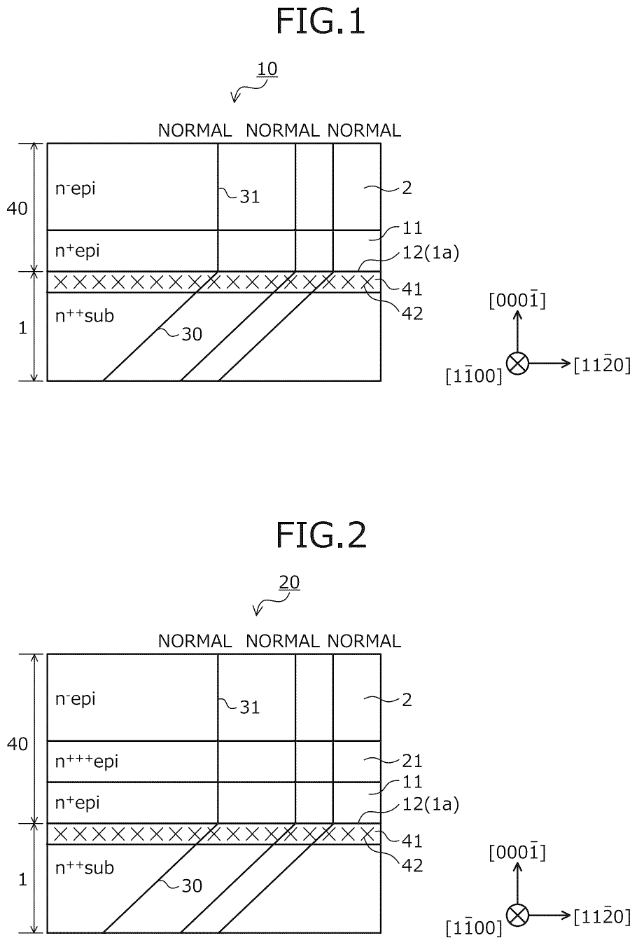

A structure of a silicon carbide wafer according to an embodiment that solves the above problems will be described below. FIGS. 1 and 2 are cross-sectional views depicting examples of the structure of a silicon carbide wafer used in a silicon carbide semiconductor device according to an embodiment. The silicon carbide semiconductor device according to the embodiment uses SiC wafers 10 and 20 (FIGS. 1 and 2: epitaxial wafers) formed by growing by epitaxy, in order, one or more n-type epitaxial layers 40 (depicted as n⁺ epi, n⁺⁺⁺ epi) doped with an n-type dopant such as nitrogen (N) to form buffer layers 11 and 21, and an n⁻-type epitaxial layer 40 (depicted as n⁻ epi) to form a drift layer 2, on a front surface (main surface) 1a of a starting substrate 1 (depicted as n⁺⁺ sub: semiconductor substrate) containing silicon carbide (SiC) as a semiconductor material.

The starting substrate 1 is, for example, a bulk substrate containing single crystal 4H-SiC (4-layer periodicity hexagonal silicon carbide). A front surface 1a of the starting substrate 1 is, for example, a (0001) plane, or so-called Si-plane, having a predetermined off-angle in the <11-20> direction. Although not particularly limited hereto, the off-angle of the front surface 1a of the starting substrate 1 may be, for example, about 4 degrees±0.5 degrees. The conductivity type of the starting substrate 1 may be set as appropriate. For example, when the silicon carbide semiconductor device according to the embodiment is a MOSFET or a p-intrinsic-n (pin) diode, the starting substrate 1 is an n⁺⁺-type having a dopant concentration that is higher than a dopant concentration of the buffer layers 11 and 21. When the silicon carbide semiconductor device according to the embodiment is an IGBT, the starting substrate 1 is a p⁺⁺-type.

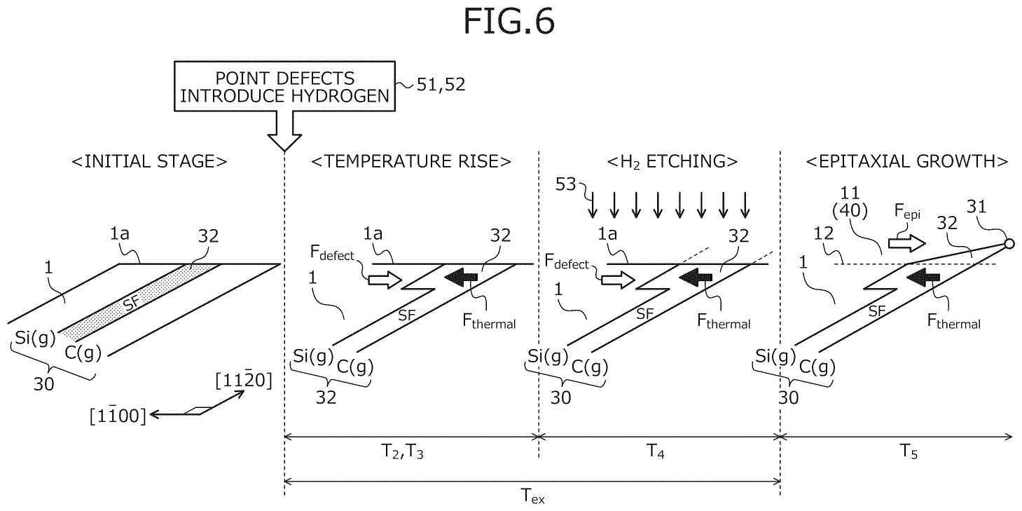

The starting substrate 1 is a SiC starting wafer cut (sliced) from a SiC ingot produced by a general sublimation method. The sublimation method is a method in which a SiC raw material is heated to, for example, about 2200 degrees C. to 2500 degrees C. to sublimate the SiC, and a generated gas species is recrystallized into a seed crystal controlled at a low temperature. In the starting substrate 1, each basal plane dislocation (BPD) 30, which is a perfect dislocation, is decomposed into the two parallel Shockley partial dislocations Si(g) and C(g) on the basal plane of the starting substrate 1 having a predetermined off-angle. A Shockley stacking fault (SF: the hatched portion of the initial starting substrate 1 depicted in FIG. 6) 32 is present between the two Shockley partial dislocations Si(g) and C(g).

The distance between the two Shockley partial dislocations Si(g) and C(g) of each BPD 30 in the starting substrate 1 fabricated by a typical sublimation method is narrow enough to convert the BPD 30 into a TED 31 at an interface 12 between the starting substrate 1 and the buffer layer 11 when a stress Fₑₚᵢ is applied from the buffer layer 11 during epitaxial growth (refer to FIG. 6 described later). For example, the distance between the two Shockley partial dislocations Si(g) and C(g) of the BPDs 30 in the starting substrate 1 in the initial stage (before heating in an annealing process for raising the temperature in the epitaxy growth furnace) is, for example, about 40 nm. The density of BPDs 30 in the starting substrate 1 is, for example, about 100/cm² to 3000/cm².

In the starting substrate 1, point defects 42 (indicated by x marks in FIGS. 1 and 2 and in FIGS. 4, 5, and 7 described below) are introduced in to a surface region (hereinafter, crystal defect introduced region) 41 from the front surface 1a of the starting substrate 1 to a predetermined depth, the crystal defect introduced region 41 having a higher density of the point defects than the remaining region of the starting substrate 1 (region excluding the crystal defect introduced region 41). The crystal defect introduced region 41 may be disposed in a portion of the starting substrate 1 where the distance between the two Shockley partial dislocations Si(g) and C(g) of a BPD 30 is likely to increase during pretreatment. For example, preferably, the crystal defect may extend to a depth of at least about 0.5 μm from the front surface 1a of the starting substrate 1.

The point defects 42 are carbon vacancy defects (Z_{1/2} centers) created by bombarding the front surface 1a of the starting substrate 1 with atoms, molecules, electron beams, or particle beams to destroy the SiC crystal structure of the starting substrate 1. For example, the point defects 42 are introduced from the front surface 1a of the starting substrate 1 by proton (H⁺) irradiation, hydrogen (H) ion implantation, electron beam irradiation, particle beam irradiation, or nitrogen (N) ion implantation. The point defects 42 function as lifetime killers for minority carriers (holes). The crystal defect introduced region 41 may contain hydrogen or nitrogen, along with the point defects 42, at higher densities than the remaining regions of the starting substrate 1.

When the point defects 42 are introduced by proton irradiation or hydrogen ion implantation, the crystal defect introduced region 41 contains hydrogen atoms (H) or hydrogen molecules (H₂) that function as minority carrier lifetime killers, together with the point defects 42, in at least a surface region of the starting substrate 1, at the front surface 1a thereof. When the point defects 42 are introduced by nitrogen ion implantation, the crystal defect introduced region 41 contains nitrogen atoms that function as minority carrier lifetime killers, together with the point defects 42, in at least a surface region of the starting substrate 1, at the front surface 1a thereof. Since electron beam irradiation or particle beam irradiation is applied to the entire starting substrate 1, the entire starting substrate 1 becomes the crystal defect introduced region 41 (refer to FIG. 5 described later).

For a method such as ion implantation for introducing the point defects 42 only to a certain depth from the front surface 1a of the starting substrate 1, the deeper and more densely the point defects 42 are introduced, the higher the manufacturing cost. However, when, for example, nitrogen ion implantation is used to form the crystal defect introduced region 41 having a nitrogen concentration of, for example, about 5×10¹⁸/cm³ or more but not more than 2×10¹⁹/cm³, both the point defects 42 and nitrogen are introduced in to the crystal defect introduced region 41. Therefore, both the energy level formed by nitrogen and the point defects 42 function as minority carrier lifetime killers. On the other hand, when the point defects 42 are introduced by electron beam irradiation, the point defects 42 may be introduced to exhibit a uniform density distribution in the depth direction throughout the entire starting substrate 1, without increasing manufacturing costs.

Configuration may be such that the crystal defect introduced region 41 is disposed the SiC wafers 10 and 20, only in a portion thereof that faces the bipolar operating portion in the depth direction. The bipolar operating portion is a portion where a pn junction is formed that is electrically connected to a surface electrode such as a source electrode 75. The crystal defect introduced region 41 has a function of impeding movement of the Si core partial dislocations Si(g) of the BPDs 30 in the starting substrate 1. The density of the point defects 42 in the crystal defect introduced region 41 is, for example, about 1×10¹¹/cm³ or more but not more than 3×10¹⁸/cm³. The density of the point defects 42 in the crystal defect introduced region 41 may be preferably highest at the interface 12 between the starting substrate 1 and the buffer layer 11. The density of the point defects 42 in the crystal defect introduced region 41 may be uniform in the depth direction.

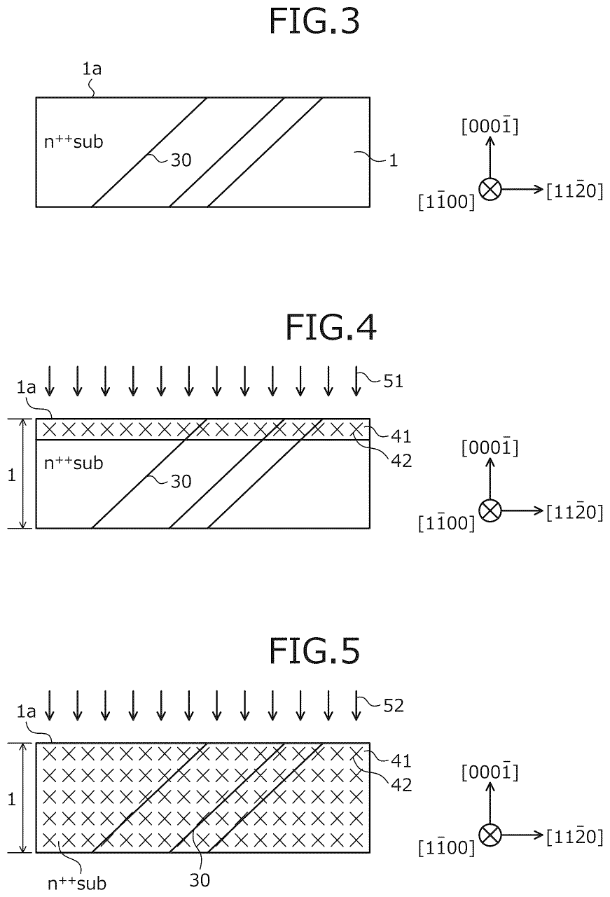

Introduction 51 and 52 of the point defects 42 in to the starting substrate 1 (refer to FIGS. 3 to 6 described later) is performed before epitaxial growth of the epitaxial layer 40 that constitutes the buffer layers 11 and 21 and the drift layer 2, etc. Thus, the point defects 42 are introduced only in to the starting substrate 1, not in to epitaxial layer 40. By not introducing the point defects 42 in to the drift layer 2, it is possible to prevent the point defects 42 from adversely affecting the electrical characteristics of the silicon carbide semiconductor device. The starting substrate 1 contains more point defects 42 than the epitaxial layer 40. The starting substrate 1 may contain more dopant that acts as minority carrier lifetime killers than the epitaxial layer 40.

The buffer layers 11 and 21, and the drift layer 2 are grown by epitaxy consecutively in the same epitaxy growth furnace, with the dopant concentrations and thicknesses appropriately controlled. This prevents degradation of film quality at the interface between the buffer layer 11 and the drift layer 2. The buffer layer 11 is an n⁺-type, with a dopant concentration higher than the dopant concentration of the n⁻-type drift layer 2. The buffer layer 11 is disposed between and in contact with the drift layer 2 and the starting substrate 1, and is in contact with the crystal defect introduced region 41 at the front surface 1a of the starting substrate 1. The buffer layer 11 is a dislocation conversion layer that converts BPDs 30 in the starting substrate 1 into the threading edge dislocations (TEDs) 31 during epitaxial growth of the buffer layer 11.

Growth of the buffer layer 11 on the front surface 1a of the starting substrate 1 by epitaxy enables suppression of the propagation of BPDs 30 in the starting substrate 1 to the epitaxial layer. The buffer layer 21 may be disposed between the buffer layer 11 and the drift layer 2 (FIG. 2). In this case, buffer layer 21 is in contact with the drift layer 2. Buffer layer 21 is an n⁺⁺⁺-type and has a dopant concentration that is higher than the dopant concentration of the n⁺-type buffer layer 11. Buffer layer 21 has a function of suppressing the expansion of SFs 32 from the BPDs 30 in the starting substrate 1 by eliminating holes supplied from the drift layer 2 through recombination during bipolar operation of the silicon carbide semiconductor device.

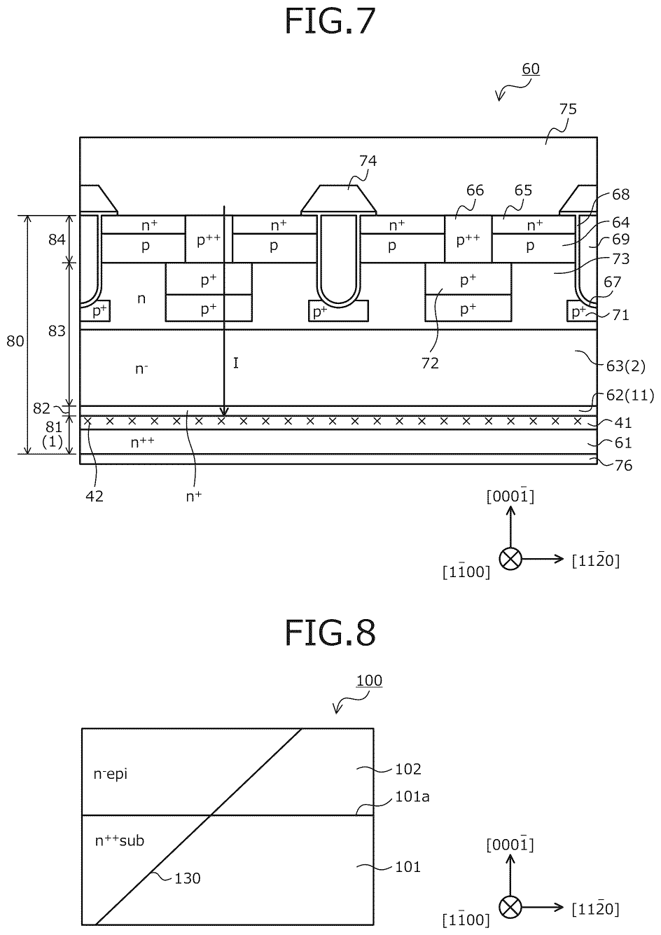

A device structure of a bipolar device such as the IGBT, or a device structure that parasitically operates in a bipolar manner, such as the MOSFET or the pin diode, is formed above the surface of the drift layer 2, opposite to the surface thereof facing the starting substrate 1, or is formed in the drift layer 2, or both. When the silicon carbide semiconductor device is an IGBT, the buffer layer 11 may be an n-type with a lower n-type dopant concentration than that of the starting substrate 1, which is p⁺⁺-type, and the buffer layer 21 may be a p⁺⁺⁺-type with a higher p-type dopant concentration than that of the buffer layer 11 and the starting substrate 1, which are an n⁺-type and a p⁺⁺-type, respectively. A structural example of a silicon carbide semiconductor device according to an embodiment will be described later (refer to FIG. 7).

A method of manufacturing a silicon carbide semiconductor wafer according to an embodiment and a method of manufacturing a silicon carbide semiconductor device according to an embodiment will be described. FIGS. 3 and 4 are cross-sectional views schematically depicting states during the manufacturing of a silicon carbide wafer used in a silicon carbide semiconductor device according to an embodiment. FIG. 5 is a cross-sectional view schematically depicting another example of a state during the manufacturing of the silicon carbide wafer used in the silicon carbide semiconductor device according to an embodiment. First, the starting substrate 1 is prepared (FIG. 3). The starting substrate 1 contains the BPDs 30 on the basal plane of the starting substrate 1, which has a predetermined off-angle.

Next, the point defects 42 are introduced into the front surface 1a of the starting substrate 1 by proton irradiation, hydrogen ion implantation, electron beam irradiation, particle beam irradiation, or nitrogen ion implantation, thereby forming the crystal defect introduced region 41 in the starting substrate 1. Introduction 51 of the point defects 42 by proton irradiation, hydrogen ion implantation, or nitrogen ion implantation forms the crystal defect introduced region 41 in the starting substrate 1, at a predetermined depth from the front surface 1a thereof (FIG. 4: introduction process). The introduction (52) of the point defects 42 by electron beam irradiation or particle beam irradiation converts the entire starting substrate 1 into the crystal defect introduced region 41 (FIG. 5: introduction process).

Next, the starting substrate 1 is inserted in to the epitaxy growth furnace (not depicted), and the temperature in the epitaxy growth furnace is raised to a predetermined epitaxial growth temperature. Then, hydrogen etching 53 (refer to FIG. 6 described below) is performed while maintaining the temperature in the epitaxy growth furnace in the vicinity of the epitaxial growth temperature, thereby cleaning the front surface 1a of the starting substrate 1. Then, with the interior of the epitaxy growth furnace maintained at the epitaxial growth temperature, the epitaxial layer 40 is grown on the front surface 1a of the starting substrate 1 by epitaxy (film formation process).

For example, in the same epitaxy growth furnace, the epitaxial layers 40 that constitute the buffer layer 11 and the drift layer 2 are successively grown by epitaxy in this order on the front surface 1a of the starting substrate 1 while being doped with dopant of a predetermined conductivity type, thereby completing the SiC wafer 10 depicted in FIG. 1 (first step). The n-type impurity doped in to the epitaxial layer 40 may be, for example, nitrogen (N). The p-type impurity doped in to the epitaxial layer 40 may be, for example, aluminum (Al).

At this time, the epitaxial layers 40 that constitute the buffer layers 11 and 21 and the drift layer 2 are grown by epitaxy in this order in the same epitaxy growth furnace, thereby completing the SiC wafer 20 depicted in FIG. 2 (first step). The temperature profile in the epitaxy growth furnace may be the general temperature profile depicted in FIG. 12. Thereafter, a predetermined device structure of a silicon carbide semiconductor device is formed in the epitaxial layer 40 (in the drift layer 2, or above the surface of the drift layer 2, or both) by a general method (second step).

The SiC wafers 10 and 20 may include, as the epitaxial layer 40, a SiC layer in which the device structure of a silicon carbide semiconductor device is configured and grown by epitaxy successively on the drift layer 2 in the same epitaxy growth furnace, or grown by epitaxy on the surface of the drift layer 2 after a process of forming diffused regions of predetermined conductivity types by ion implantation. Then, surface electrodes are formed on the first and second main surfaces (front and back surfaces) of the SiC wafers 10 and 20, respectively, by a general method (third and fourth steps), whereby the silicon carbide semiconductor device according to the embodiment is completed.

When fabricating the SiC wafers 10 and 20, by forming the crystal defect introduced region 41 in the starting substrate 1 before epitaxial growth of the epitaxial layer 40, the efficiency with which the BPDs 30 in the starting substrate 1 are converted to the TEDs 31 (BPD-TED conversion efficiency) is stabilized. A reason for this is as follows. FIG. 6 is an explanatory diagram schematically depicting a principle of BPD-TED conversion during the manufacture of the silicon carbide wafer according to the embodiment. An example will be described in which the interior of the epitaxy growth furnace is heated exhibiting the general temperature profile depicted in FIG. 12.

FIG. 6 depicts a cross-sectional view of the starting substrate 1 before insertion into the epitaxy growth furnace (initial stage), a cross-sectional view of the starting substrate 1 during heating and hydrogen etching before epitaxial growth, and a cross-sectional view of the starting substrate 1 during epitaxial growth (epi-growth). In FIG. 6, the [11-20] direction is the step-flow growth direction of the epitaxial layer 40 grown by epitaxy on the front surface 1a of the starting substrate 1, and the [1-100] direction is a direction parallel to the front surface 1a of the starting substrate 1. The periods T₂ to T₅ and Tₑₓ in FIG. 6 correspond to the annealing time in FIG. 12.

As described above, to grow the epitaxial layer 40 on the front surface 1a of the starting substrate 1 by epitaxy, the temperature in the epitaxy growth furnace into which the starting substrate 1 is inserted is raised and lowered according to the temperature profile depicted in FIG. 12. For example, after the starting substrate 1 is first inserted into the epitaxy growth furnace (not depicted), the temperature in the epitaxy growth furnace is raised to, for example, 900 degrees C. during the predetermined period T₁ (first-stage temperature rise), maintained at that temperature for the predetermined period T₂, and then further raised to a temperature close to the epitaxial growth temperature during the predetermined period T₃ (second-stage temperature rise).

With the temperature in the epitaxy growth furnace maintained at a temperature close to the epitaxial growth temperature, the front surface 1a of the starting substrate 1 is cleaned by hydrogen etching 53 for the predetermined period T₄. Then, with the interior of the epitaxy growth furnace maintained at the epitaxial growth temperature, epitaxial layers 40 that constitute the buffer layers 11 and 21 and the drift layer 2 (refer to FIGS. 1 and 2) are grown by epitaxy consecutively on the front surface 1a of the starting substrate 1 for the predetermined period T₅ by appropriately controlling the dopant concentration and thickness, and after epitaxial growth, the interior of the epitaxy growth furnace is cooled to a room temperature.

The starting substrate 1 has an internal stress F_{defect} due to the crystal defect introduced region 41 formed in advance in the starting substrate 1. During the temperature rise in the epitaxy growth furnace (temperature rise in FIG. 6), while the Si core partial dislocation Si(g) of the BPD 30 in the starting substrate 1 is subjected to the thermal stress Fₜₕₑᵣₘₐₗ in the [1-100] direction orthogonal to the step flow growth direction of the epitaxial layer 40, the crystal defect introduced region 41 generates an internal stress F_{defect} of a magnitude that is antagonistic to the thermal stress Fₜₕₑᵣₘₐₗ in a direction that pushes back the thermal stress Fₜₕₑᵣₘₐₗ, making it difficult for the dislocation to move.

As a result, the distance between the two Shockley partial dislocations Si(g) and C(g) of the BPD 30 is unlikely to increase during the temperature rise in the epitaxy growth furnace, and the expansion (area increase) of the SF 32 may be suppressed. During hydrogen etching 53, a vicinity of the newly exposed portion of the front surface 1a of the starting substrate 1 is subjected to thermal stress F, similar to the temperature increase in the epitaxy growth furnace. However, as with the temperature increase in the epitaxy growth furnace, the internal stress F due to the crystal defect introduced region 41 and the thermal stress F are nearly balanced, suppressing the expansion of SF 32.

During epitaxial growth of the epitaxial layer 40, which will become the buffer layer 11, the stress Fₑₚᵢ is applied from the buffer layer 11 to the Si core partial dislocation Si(g) in a direction that pushes back thermal stress F, in the vicinity of the front surface 1a of the starting substrate 1. This reduces the distance between the two Shockley partial dislocations Si(g) and C(g) to within the certain distance necessary for BPD-TED conversion. Thus, the BPD 30 is converted to the TED 31 at the interface 12 between the starting substrate 1 and the buffer layer 11 (refer to FIGS. 1 and 2).

Among the multiple BPDs 30 in the starting substrate 1, the BPDs 30 having a Burgers vector parallel to the step-flow growth direction of the epitaxial layer 40 are adversely affected by the thermal stress Fₜₕₑᵣₘₐₗ but may be stably converted to the TEDs 31. The BPDs 30 (not depicted) having a Burgers vector that is not parallel to the step-flow growth direction of the epitaxial layer 40 are converted to the TEDs 31 at the interface 12 between the starting substrate 1 and the buffer layer 11, irrespective of the presence or absence of the internal stress F_{defect} due to the crystal defect introduced region 41.

The TEDs 31 converted at the interface 12 between the starting substrate 1 and the buffer layer 11 propagate to the epitaxial layer 40 (buffer layers 11 and 21 and drift layer 2). This makes it possible to suppress the occurrence of abnormal BPDs 130 (refer to FIGS. 9 and 10) such as those in the SiC wafers 110 and 120 of the reference example, thereby improving the BPD-TED conversion efficiency. The TEDs 31 do not generate SFs 32 even when recombination energy is supplied. This makes it possible to suppress bipolar degradation of the silicon carbide semiconductor device.

A structure of a silicon carbide semiconductor device according to an embodiment will be described using a trench-gate MOSFET as an example. FIG. 7 is a cross-sectional view depicting an example of the structure of the silicon carbide semiconductor device according to an embodiment. A silicon carbide semiconductor device 60 depicted in FIG. 7 is a vertical MOSFET having a trench gate structure (device structure) on the front surface side of a SiC wafer 80. The SiC wafer 80 is formed by growing by epitaxy, in this order, epitaxial layers 82 to 84 that constitute an n⁺-type buffer region 62, an n⁻-type drift region 63, and a p-type base region 64 on the front surface of an n⁺⁺-type starting substrate 81 using SiC as a semiconductor material.

The SiC wafer 80 corresponds to the SiC wafer 10 depicted in FIG. 1. The SiC wafer 80 has, as the front surface, a first main surface having the p-type epitaxial layer 84 and, as the back surface, a second main surface having the n⁺⁺-type starting substrate 81 (the back surface of the n⁺⁺-type starting substrate 81). The n⁺⁺-type starting substrate 81 is, for example, an n⁺⁺-type SiC single crystal bulk substrate doped with nitrogen, and corresponds to the starting substrate 1 in FIG. 1. The n⁺⁺-type starting substrate 81 constitutes an n⁺⁺-type drain region 61. In the n⁺⁺-type starting substrate 81, the crystal defect introduced region 41, in which the point defects 42 are introduced (refer to FIG. 4 regarding introduction process 51), is provided. The entire n⁺⁺-type starting substrate 81 may be the crystal defect introduced region 41 (refer to FIG. 5).

The epitaxial layers 82 to 84 correspond to the epitaxial layer 40 in FIG. 1. The n⁺-type epitaxial layer 82 and the n-type epitaxial layer 83 correspond to the buffer layer 11 and the drift layer 2 in FIG. 1, respectively. The n⁺-type epitaxial layer 82 and the n⁻-type epitaxial layer 83 are doped with, for example, nitrogen. The n⁺-type epitaxial layer 82 constitutes the n⁺-type buffer region 62. The n⁺-type buffer region 62 is in contact with the n⁺⁺-type drain region 61 and the n-type drift region 63. A portion of the n⁻-type epitaxial layer 83 excluding p⁺-type regions 71 and 72 and an n-type current diffused region 73, which will be described later, constitutes the n-type drift region 63.

An n⁺⁺⁺-type epitaxial layer that serves as an n⁺⁺⁺-type buffer region (not depicted) may be provided between the n⁺-type buffer region 62 and the n⁻-type drift region 63. The n⁺⁺⁺-type epitaxial layer serving as this n⁺⁺⁺-type buffer region corresponds to the buffer layer 21 in FIG. 2. In an instance in which the n⁺⁺⁺-type buffer region is provided, the SiC wafer 80 corresponds to the SiC wafer 20 in FIG. 2. The p-type epitaxial layer 84 is doped with a p-type dopant, such as aluminum. A portion of the p-type epitaxial layer 84 excluding n⁺-type source regions 65 and p⁺⁺-type contact regions 66 (described later) constitutes the p-type base region 64.

The trench gate structure is configured by the p-type base region 64, the n⁺-type source regions 65, the p⁺⁺-type contact regions 66, trenches 67, gate insulating films 68, and gate electrodes 69. The p-type base region 64 is provided between the front surface of the SiC wafer 80 and the n⁻-type drift region 63. The n⁺-type source regions 65 and the p⁺⁺-type contact regions 66 are diffused regions formed in the p-type epitaxial layer 84 by ion implantation. The n⁺-type source regions 65 and the p⁺⁺-type contact regions 66 are selectively provided between the front surface of the SiC wafer 80 and the p-type base region 64, and are in contact with the p-type base region 64.

The n⁺-type source regions 65 and the p⁺⁺-type contact regions 66 are in contact with the source electrode 75 at the front surface of the SiC wafer 80. The p⁺⁺-type contact regions 66 may be omitted. In this case, the p-type base region 64 reaches the front surface of the SiC wafer 80, instead of the p⁺⁺-type contact regions 66. The trenches 67 penetrate through the n⁺-type source regions 65 and the p-type base region 64 in the depth direction from the front surface of the SiC wafer 80, and terminate in the n-type current diffused region 73 (or in the p⁺-type regions 71 via the n-type current diffused region 73), which will be described later. The gate electrodes 69 are disposed in the trenches 67, with the gate insulating films 68 interposed therebetween.

Between the p-type base region 64 and the n⁻-type drift region 63, the n-type current diffused region 73 and the p⁺-type regions 71 are selectively disposed at positions deeper toward the n⁺⁺-type drain region 61 than are the trenches 67. The p⁺-type regions 71 are disposed apart from each other in portions facing the bottom surfaces of the trenches 67 and in portions between adjacent trenches among the trenches 67, and are connected (not depicted), for example, in a direction of view of FIG. 7. The p⁺-type regions 72 are disposed between and in contact with the p-type base region 64 and the p⁺-type regions 71. The p⁺-type regions 71 and 72 and the n-type current diffused region 73 are diffused regions formed by ion implantation in the n⁻-type epitaxial layer 83.

All of the p⁺-type regions 71 and 72 are fixed to the potential of the source electrode 75, and have the function of depleting when the MOSFET is off (or depleting the n-type current diffused region 73, or both) to relax the electric field applied to the gate insulating films 68. The p⁺-type regions 71 are provided apart from the p-type base region 64. The p⁺-type regions 71 that are directly below the trenches 67 (the n⁺⁺-type drain region 61 side) may be in contact with the gate insulating films 68 at the bottoms of the trenches 67, or may be apart from the trenches 67. The p⁺-type regions 71 and 72 between adjacent trenches of the trenches 67 are provided apart from the trenches 67.

The n-type current diffused region 73 is a so-called current spreading layer (CSL) that reduces the spreading resistance of carriers. The n-type current diffused region 73 is adjacent to the p⁺-type regions 71 and 72 and the trenches 67, and has an upper surface (the surface on the n⁺-type source regions 65 side) that is in contact with the p-type base region 64 and a lower surface (the surface on the n⁺⁺-type drain region 61 side) that is in contact with the n⁻-type drift region 63. The n-type current diffused region 73 may be omitted. In this case, instead of the n-type current diffused region 73, the n⁻-type drift region 63 extends between the adjacent p⁺-type regions 71 to the p-type base region 64 and reaches the trenches 67 in a direction parallel to the front surface of the SiC wafer 80.

An interlayer insulating film 74 is provided over almost the entire front surface of the SiC wafer 80 and covers the gate electrodes 69. The source electrode (first electrode) 75 is forms an ohmic junction with the SiC wafer 80 in contact holes in the interlayer insulating film 74, and is electrically connected to the n⁺-type source regions 65, the p⁺⁺-type contact regions 66, and the p-type base region 64. A drain electrode (second electrode) 76 is disposed on the entire back surface of the SiC wafer 80 (the back surface of the n⁺⁺-type starting substrate 81). The drain electrode 76 is forms an ohmic junction with the back surface of the SiC wafer 80, and is electrically connected to the n⁺⁺-type drain region 61 (the n⁺⁺-type starting substrate 81).

In the silicon carbide semiconductor device (MOSFET) according to the above-described embodiment, in addition to a mode (synchronous rectification mode) in which a current flows through a channel (an n-type inversion layer formed along the sidewalls of the trenches 67 in the p-type base region 64), there is also a mode (bipolar mode) in which a current I flows forward through a body diode. The body diode is a parasitic pn junction diode formed by pn junctions between the p⁺⁺-type contact regions 66, the p-type base region 64, the p⁺-type regions 71 and 72, the n-type current diffused region 73, the n⁻-type drift region 63, the n⁺-type buffer region 62, and the n⁺⁺-type drain region 61.

During the bipolar operation (bipolar mode) of the silicon carbide semiconductor device, when the BPDs 30 in the n⁻-type drift region 63 are supplied with a certain amount of recombination energy generated by the recombination of carriers (electrons and holes) in the n⁻-type drift region 63, the BPDs 30 expand while forming Shockley-type SFs, and the on-voltage increases over time, resulting in an increase in the forward voltage of the silicon carbide semiconductor device (bipolar degradation). The silicon carbide semiconductor device according to the present embodiment is fabricated using the n⁺⁺-type starting substrate 81 in which the crystal defect introduced region 41 has been formed in advance, thereby increasing the BPD-TED conversion efficiency.

By forming the crystal defect introduced region 41 in the n⁺⁺-type starting substrate 81, during epitaxial growth of the n⁺-type buffer region 62 (n⁺-type epitaxial layer 82), the BPDs 30 in the n⁺⁺-type starting substrate 81 may be converted to the TEDs 31 with high efficiency and stability at the interface between the n⁺⁺-type starting substrate 81 and the n⁺-type buffer region 62 (refer to FIG. 6). Thus, the TEDs 31 propagate to the n⁻-type drift region 63, and the BPDs 30 in the n⁺⁺-type starting substrate 81 are unlikely to continue. The TEDs 31 do not generate SFs 32 even when supplied with recombination energy. Therefore, bipolar degradation of the silicon carbide semiconductor device may be suppressed.

When the silicon carbide semiconductor device according to the embodiment depicted in FIG. 7 is applied to an IGBT, a p⁺⁺-type starting substrate corresponding to the starting substrate 1 depicted in FIG. 1 may be disposed instead of the n⁺⁺-type starting substrate 81. In this case, the n⁺-type epitaxial layer 82 that constitutes the n⁺-type buffer region 62 and the n⁺⁺⁺-type epitaxial layer that constitutes the n⁺⁺⁺-type buffer region may be left as they are. When the silicon carbide semiconductor device according to the above-described embodiment is applied to a pin diode, the trench gate structure may be omitted, and the p-type epitaxial layer 84 may serve as a p-type anode region.

As described above, according to the embodiment, a crystal defect introduced region is formed by introducing point defects at a high density in to at least the surface region of the starting substrate, at the front surface thereof before the epitaxial growth of an epitaxial layer including a buffer layer (a transition conversion layer that converts BPDs in the starting substrate to TEDs during epitaxial growth). The crystal defect introduced region makes it difficult for Si core partial dislocations of BPDs to move in the vicinity of the front surface of the starting substrate. Therefore, even when the temperature of the front surface of the starting substrate, the temperature distribution in the starting substrate, and the heating time of the starting substrate vary and become unstable in the temperature environment during annealing treatment (a pretreatment in which the starting substrate is heated with a temperature profile having a high temperature gradient before epitaxial growth) to increase the temperature in the epitaxy growth furnace, the distance between the two Shockley partial dislocations that constitute each of the BPDs in the starting substrate is unlikely to widen.

Because the distance between two Shockley partial dislocations of the BPDs in the starting substrate remains almost unchanged even after pretreatment, stress from the buffer layer during the subsequent epitaxial growth of the buffer layer is received and the distance between two Shockley partial dislocations of BPDs in the starting substrate may be reduced to a certain value or less. As a result, BPDs in the starting substrate are stably and efficiently converted to TEDs at the interface between the starting substrate and the buffer layer, making propagation thereof to the buffer layer difficult. That is, the crystal defect introduced region in the starting substrate stabilizes the BPD-TED conversion efficiency, the propagation of BPDs in the starting substrate is suppressed and the number of BPDs in the drift layer is reduced. Thus, an increase in on-state voltage over time may be suppressed, and an increase in the forward voltage (bipolar degradation) of a silicon carbide semiconductor device may be suppressed.

Furthermore, according to the embodiment, the BPD-TED conversion efficiency may be improved irrespective of the temperature profile during epitaxial growth, and no setting changes or special control mechanisms are necessary for controlling the temperature distribution in the starting substrate during epitaxial growth. Therefore, increases in manufacturing costs may be suppressed.

As described above, the present disclosure is not limited to the above-described embodiments, and various modifications not departing from the spirit of the present disclosure may be made. In the above-described embodiments, while the first conductivity type is an n-type and the second conductivity type is a p-type, the present disclosure is similarly implemented when the first conductivity type is a p-type and the second conductivity type is an n-type.

According to the silicon carbide wafer, the method of manufacturing a silicon carbide wafer, the silicon carbide semiconductor device, and the method of manufacturing a silicon carbide semiconductor device according to the present disclosure, the propagation of BPDs in a starting substrate may advantageously be suppressed.

As set forth hereinabove, the silicon carbide wafer, silicon carbide wafer manufacturing method, silicon carbide semiconductor device, and silicon carbide semiconductor device manufacturing method according to the present disclosure are useful for power semiconductor devices used in power converting equipment, power supply devices for various industrial machines, and the like, and are particularly suitable for bipolar devices and silicon carbide semiconductor devices having a device structure that operates parasitically in a bipolar manner.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide wafer, comprising:
a semiconductor substrate containing silicon carbide and having a first surface and a second surface opposite to each other;
an epitaxial layer provided at the first surface of the semiconductor substrate and having a dopant concentration lower than that a dopant concentration of the semiconductor substrate; and
a crystal defect introduced region provided in the semiconductor substrate, at a predetermined depth from the first surface of the semiconductor substrate, the crystal defect introduced region being in contact with the epitaxial layer and containing a number of point defects that are atomic vacancies created by irradiation of an electron beam on the semiconductor substrate.

2. The silicon carbide wafer according to claim 1, wherein
the semiconductor substrate contains a larger number of the point defects than the epitaxial layer.

3. The silicon carbide wafer according to claim 1, wherein
the crystal defect introduced region is provided only in a region of the semiconductor substrate, at the first surface thereof.

4. The silicon carbide wafer according to claim 3, wherein
the semiconductor substrate contains hydrogen or nitrogen in the crystal defect introduced region.

5. A silicon carbide semiconductor device comprising:
a silicon carbide wafer having a first main surface and a second main surface, the silicon carbide wafer including:
a semiconductor substrate containing silicon carbide and having a first surface and a second surface opposite to each other, the second surface constituting the second main surface of the silicon carbide wafer,
an epitaxial layer disposed at the first surface of the semiconductor substrate and having a dopant concentration lower than a dopant concentration of the semiconductor substrate, the epitaxial layer having a first surface and a second surface opposite to each other, the first surface of the epitaxial layer constituting the first main surface of the silicon carbide wafer, and the second surface of the epitaxial layer facing the semiconductor substrate, and
a crystal defect introduced region provided in the semiconductor substrate, at a predetermined depth from the first surface of the semiconductor substrate, the crystal defect introduced region being in contact with the epitaxial layer and containing a number of point defects that are atomic vacancies created by irradiation of an electron beam on the semiconductor substrate;
a device structure provided in the silicon carbide wafer, at the first main surface;
a first electrode provided on the first main surface and electrically connected to the device structure;
a second electrode provided at the second main surface; and
a pn junction provided in the silicon carbide wafer and operating in a bipolar mode between the first electrode and the second electrode.

6. A method of manufacturing a silicon carbide wafer, the method comprising:
providing a semiconductor substrate containing silicon carbide and having a first surface and a second surface opposite to each other,
introducing atomic vacancies as point defects from the first surface of the semiconductor substrate, the atomic vacancies being introduced to a predetermined depth by irradiation of an electron beam to the first surface of the semiconductor substrate, thereby forming a crystal defect introduced region; and
growing, by epitaxy, an epitaxial layer on the first surface of the semiconductor substrate, the epitaxial layer being in contact with the crystal defect introduced region and having a dopant concentration lower than a dopant concentration of the semiconductor substrate.

7. The method of manufacturing the silicon carbide wafer according to claim 6, wherein
the growing the epitaxial layer includes raising a temperature in an epitaxy growth furnace up to an epitaxial growth temperature with the semiconductor substrate loaded in the epitaxy growth furnace and growing, by epitaxy, the epitaxial layer at the epitaxial growth temperature.

8. A method of manufacturing a silicon carbide semiconductor device, the method comprising:
as a first process, fabricating a silicon carbide wafer containing silicon carbide and having a first main surface and a second main surface opposite to each other;
as a second process, forming a device structure in the silicon carbide wafer, at the first main surface;
as a third process, forming a first electrode on the first main surface, the first electrode being electrically connected to the device structure; and
as a fourth process, forming a second electrode on the second main surface of the silicon carbide wafer; and
forming a pn junction in the silicon carbide wafer, between the first electrode and the second electrode, before the third process, the pn junction being configured to operate in a bipolar mode, wherein
the first process includes:
preparing a semiconductor substrate containing silicon carbide and having a first surface and a second surface opposite to each other,
introducing atomic vacancies as point defects in the semiconductor substrate, thereby forming a crystal defect introduced region, the atomic vacancies being introduced to a predetermined depth from the first surface of the semiconductor substrate by irradiation of an electron beam from the first surface of the semiconductor substrate, and
growing, by epitaxy, an epitaxial layer on the first surface of the semiconductor substrate, the epitaxial layer being in contact with the crystal defect introduced region and having a dopant concentration lower than a dopant concentration of the semiconductor substrate, the epitaxial layer having a first surface and a second surface opposite to each other, the second surface of the epitaxial layer facing the semiconductor substrate, and
the first surface of the epitaxial layer constitutes the first main surface of the silicon carbide wafer and the second surface of the semiconductor substrate constitutes the second main surface of the silicon carbide wafer.
